(19) United States
(12) Patent Application Publication
(10) Pub. No.: US 2004/0075140 A1
(43) Pub. Date: Apr. 22, 2004

(54) Microsensor and single chip integrated microsensor system

(76) Inventors: Henry Baltes, Zurich (CH); Diego Barrettino, Fluelen (CH); Markus Graf, Zurich (CH); Christoph Hagleitner, Wallisellen (CH); Andreas Hierlemann, Zurich (CH)

Correspondence Address: BACHMAN & LAPOINTE, P.C., 900 CHAPEL STREET, SUITE 1201, NEW HAVEN, CT, 06510, US

(21) Appl. No.: 10/451,709

(22) PCT Filed: Dec. 11, 2001
(86) PCT No.: PCT/IB01/02491

(30) Foreign Application Priority Data
Dec. 20, 2000 (DE) 10063972.0
Mar. 12, 2001 (DE) 10112079.6

(51) Int. Cl. H01L 27/01

(52) U.S. Cl. 257/347

(57) ABSTRACT

A microsensor system, in particular gas sensor system, is integrated on a single chip and includes a microsensor, preferably a resistive-film-sensor configuration, with a microheater, the latter preferably of essentially round, elliptic or polygonal structure. The microsensor is located on a thermally insulated semiconductor structure, e.g. a thin membrane. Further included or integrated on the chip may be one or more first circuits for controlling the microheater and/or second circuits for evaluating or processing the measured values obtained from the microsensor. The first circuits may include power and/or temperature controller for the microheater. The second circuits may include an A/D converter, a digital signal processor, a digital output interface for processing sensor signals and transferring them to external devices, and/or potentiostats to regulate the electrode potential applied to the gas-sensitive layer. Also provided on a single chip may be a plurality of microsensors and microheaters with associated integrated circuits. The latter may then include multiplexing circuits for the sensor and the heater signals.

### DESCRIPTION

1. Technical Field

The present invention relates to microsensors, especially to gas sensors, using micromachined structures, preferably so-called micro-hotplates and associated circuitry, preferably integrated on a single chip. Such hotplates usually include a membrane, a heater, one or more temperature sensors, and an impedance-measuring device with a plurality of electrodes covered with a sensing layer, e.g. a gas-sensitive metal oxide. The novel type of hotplate according to the invention may be further integrated into a single chip sensor system comprising, apart from the hotplate, circuitry for heater supply and control and/or sensor signal readout and processing. Such a single chip sensor may advantageously be used in or serve as a smart sensor system.

2. Background of the Invention and Prior Art

Conventional microhotplates, as described by J. S. Suehle, R. E. Cavicchi, M. Gaitan and S. Semancik in “Tin Oxide Gas Sensor Fabricated Using CMOS icro-Hotplates and In-Situ Processing”, IEEE Electron Device Letter 14 (1993), pp. 118, or by I. Simon, N. Bârsan, M. Bauer and U. Weimar in “Micromachined Metal Oxide Gas Sensors: Opportunities to Improve Sensor Performance”, Sensors and Actuators B73 (2001), pp. 1, are produced in CMOS-compatible processes and do not include any integrated control or drive circuits.

Conventional micro-hotplate heaters normally include resistive heating elements, as shown in the papers mentioned above. Driving such a resistive heater on a chip usually requires a power transistor. Across this transistor, a voltage drop occurs and thus a significant fraction of the consumed power is dissipated without control.

Götz et al describe in “A novel methodology for the manufacturability of robust CMOS semiconductor gas sensor arrays”, Sensors and Actuators, vol. B 77 (2001), pp. 395-400, a CMOS hotplate suspended, however, with the help of a glass wafer bonded on top of the CMOS substrate. The described device consists of a low-power semiconductor gas sensor array, fabricated on a thermally isolated silicon diaphragm. As shown in the drawing, this diaphragm is suspended with the help of an additional, bonded glass structure, clearly. Without the glass wafer bonded to the silicon wafer, there would be no mechanical support of the membrane structure since the etching goes all the way through the layer stack of the chip. Metal lines are used as contacts along one edge of the diaphragm, which, on the one hand, are not suitable to mechanically suspend the membrane and, on the other hand, can only be realized since the membrane is mechanically supported by the glass add-on. Therefore, the device proposed in the paper by Goetz et al. is not a monolithic solution, but a two-wafer composite. Such a glass structure leads to additional fabrication steps and costs. Further, the possible stress exerted on the membrane upon heating because of the different thermal expansion coefficients may provide a problem. The same is true for the significant heat losses to the substrate via the glass posts. Mechanical and thermal stress by the different material properties of glass and the membrane is certainly unavoidable in the Götz et al design. The rather bulky glass suspensions will lead to a significant heat loss via the suspension and the power consumption of the device will be much larger as compared to the consumption of a very thin dielectric membrane.

Nowhere in Götz et al is the integration of circuitry into the design addressed or shown.

It also seems that the general concept shown in the Götz et al publication is only an artist's rendering of a design which has not been implemented, since the experimental results in the paper include only some hotplate prototypes and glass suspension prototypes.

It would be of great advantage to avoid any glass or similar suspension and to use a monolithic solution for a microsensor system. This would minimize stress within the microsensor structure and allow an integrated, straightforward manufacturing process, which in turn would maximize the yield.

Industrial CMOS-processes beside the monolithic integration of electronic and micromachined components offer the advantageous possibility of using active elements for heating by integrating the MOS-transistor on the membrane. Thus, the power transistor that drives the heater can be eliminated, and new control modes become possible. Furthermore, the full supply voltage range can be applied directly to the heater.

A somewhat similar approach using silicon-on-insulator (SOI) technology has been proposed by J. W. Gardner et al. in “Design and simulations of SOI CMOS micro-hotplate gas sensors”, Sensors and Actuators (Chemical). vol. B 78 (2001), no.1-3, pp.180-90. The apparently same design is shown in Gardner et al U.S Pat. No. 6,111,280. Gardner et al., however, propose a device only for SOI (Silicon On Insulator) technology and do not envisage the possibility of using it in conventional CMOS technology. This can clearly be seen from claim 1 of the US patent where “a gas-sensing semiconductor device comprising a semiconductor substrate, a thin insulating layer on one side of the substrate, and a thin semiconducting layer on top of the thin insulating layer . . . ” is claimed. This semiconducting layer on top of the insulating layers is not available in conventional, non-SOI CMOS technology. The patent hence refers exclusively to SOI technology, which is not only different from and much more expensive than the industrial standard CMOS technology, but is just the solution whose disadavantages the present invention wants to vercome. Gardner et al. also explicitly state in Sensors-and-Actuators-B-(Chemical). vol. B78, no.1-3; 2001; pp.180-90: “By proposing the design . . . using SOI technology, both the heater and gas-sensitive material can operate at much higher temperatures (up to 350° C.) than would normally expected for a CMOS process. MOSFET gas sensors based on a standard silicon process can only operate up to about 200° C., above which the junctions break down and so give poor device stability.”

Gardner et al. use SOI-technology since they do not have the possibility to stop the silicon etching at the n-well. The SOI oxide layer is hence needed as an etch stop.

Contrary to that includes the present invention a specially designed FET heater fabricated by using an electrochemical etch-stop technique, which stops etching at the n-well of the standard CMOS-wafer. Thus, the whole device can be produced in conventional CMOS technology and, in fact, be operated at temperatures up to 400° C.

SOI technology is not only quite different from and more difficult to handle than standard CMOS technology, but also much more expensive than the latter, since the production of the wafer starting material requires much more efforts and processing steps. Another disadvantage of SOI besides its higher material costs is, that there is considerable heat losses from the heated area to the bulk chip due to the silicon-on-insulator layer stack (mainly the silicon, which is a good thermal conductor and the thick oxide layer) as compared to the very thin layers of the poor heat conductors Si-nitride and Si-oxide, which form the membrane materials in the standard CMOS-process. This leads to enhanced power consumption of the SOI-microhotplates especially at higher operation temperatures.

Therefore, a sensor and sensor system manufactured in the less expensive and easier-to-handle conventional CMOS technology operating at a temperature of 350° C.—or even at higher temperatures—provides great advantages compared to an SOI-design.

Published PCT patent application WO 00/75649 by Briand et al. shows a microhotplate used in conjunction with a so-called GASFET, i.e. a gas-sensitive Field Effect Transistor. Claimed are single electronic components in the membrane or island, such as a transistor or a resistor, which are used as heaters and sensor transducers. However, this patent application does not refer to or address a system combining or integrating a hotplate bearing those single electronic components with more complex circuits, such as control or smart electronics on the same membrane in a monolithic approach. The authors neither show nor mention any control and/or driving circuits. Also, the use of the preferred CMOS or any equivalent technology, which would enable easy co-integration of circuits and transducers, is not mentioned or envisaged.

Baltes et al. mention in “The electronic nose in Lilliput”, IEEE Spectrum, vol. 35, September 1998, no. 9, pp. 35-38, and in “Micromachined thermally based CMOS microsensors”, Proc. IEEE, vol. 86, August 1998, pp.1660-1678, the use of CMOS technology for devising integrated chemical sensors such as polymer-based cantilevers and temperature-stabilized capacitors operated at room temperature up to a maximum of 50-80° C. Polymer-based sensors are used at room temperature, and are not intended to operate at temperatures higher than maximal 80° C., since the analyte absorption in the polymer is drastically reduced at higher temperatures, and as a consequence the sensor signal is no more detectable. Baltes et al. did not envisage the realization of microhotplates. On the contrary, they even explicitly excluded the use of CMOS technology for microhotplate sensors at that time (IEEE Spectrum, September 1998): “The fact that the polymers are applied to the CMOS-IC at room temperature is crucial. The metal oxides used in the sensors of several commercial electronic noses would have had to be applied above the CMOS limit of 350° C., disqualifying them for this application.”

European patent EP 0 291 462 B1 by Grisel discloses a microsensor produced in a semiconductor substrate, essentially a hotplate, which can be coated with a gas-sensitive layer and thus serves as a gas sensor.

Whereas the use of semiconductor device manufacturing technology is addressed in this patent, the disclosed resistance-type thin-film sensor does not include any integrated control or drive circuits.

Suehle et al. U.S. Pat. No. 5,464,966 and Semancik et al. U.S. Pat. No. 5,345,213 disclose micro-hotplate devices and methods for their fabrication based on commercial CMOS-compatible micromachining techniques. The authors report on spider-like structures generated by a front-side etching technology. The use of semiconductor device manufacturing and even CMOS technology is addressed in this patent, the disclosed resistance-type thin-film sensor does, however, again not include any integrated control or drive circuits.

Park et al. U.S. Pat. No. 5,605,612 discloses a thin-film gas sensor comprising a silicon substrate with a gas sensing layer, electrodes, and a resistance heater, the sensing layer and the heater uniformly distributed in zigzag lines on said silicon surface. Whereas the use of semiconductor device manufacturing technology is addressed in this patent, the disclosed resistance-type thin-film sensor does not include any integrated control or drive circuits.

German patent DE 44 32 729 C1 by Frank et al shows another design of a gas sensor, specifically directed to providing two different output signals, one depending on gas and temperature, the other being only temperature-dependent. The sensor has opposed, comb-like interleaving arrangements of sensor electrodes and heating elements manufactured in semiconductor technology. The integration of control or drive circuits is not addressed.

German published patent application DE 40 37 528 A1 by Schramm et al discloses a method for making a metal oxide gas sensor in hybrid technology, resulting in a relatively low power consumption of the device. The integration of control or drive circuits is nowhere addressed in this document.

The abstract of Japanese patent application 11 201 929 A by Onodera Katsumi et al. shows a membrane gas sensor comprising a multi-layer arrangement with heater, temperature sensor, and electrodes for the signals from the membrane, the electric resistance changes of which depend on the gas to be detected. The integration of control or drive circuits into the sensor is not addressed in this document.

Finally, the abstract of Japanese patent application 00 162 171 A by Suzuki Kiohiro et al shows a further gas sensor with gas-sensitive layer and associated electrodes arranged in a multi-layer structure. Again, the integration of control or drive circuits or any other switching components into the sensor is nowhere addressed in this document.

To summarize, it is apparent that a variety of solutions have been proposed showing how to integrate some of the typical elements of gas (and other) sensors, namely the heating and sensing elements, onto a semiconductor substrate. However, no document discloses any idea how to integrate further elements and/or how to solve the heat distribution issues connected with this integration. Nowhere in the prior art is disclosed to integrate control and/or driver elements onto the same semiconductor substrate or to use proven semiconductor-manufacturing methods, e.g., CMOS-technology, for this integration.

Also, none of the prior art solutions addresses the idea how to optimize the geometry of the hotplate to achieve homogeneous heat distribution and to maximize the thermal efficiency of the device. This optimization is particularly advantageous for small, portable sensor systems, where energy consumption is of critical importance. It also appears that the square membranes or hotplates mostly used in prior art approaches are not the best choice for homogeneous heat distribution and for applying droplet deposition methods of gas-sensitive layers. The reactangular form in particular leads to inhomogeneous temperature distribution (by corner effects) and non-uniform sensitive layer morphology, which in turn results in poor performance of such a sensor.

Based on the above, it is one object of this invention to identify designs of a highly integrated gas sensor, comprising the sensor itself and one or more of sensor circuitry, heater control and driver circuitry, converter circuitry, and any other circuitry required or useful for the working of the sensor system. Such designs should preferably allow the use of proven semiconductor manufacturing technologies.

Another object is to improve the temperature homogeneity and efficiency of sensors by developing an advantageous geometry of the hotplate and its components, preferably adapting them to low voltage operation. Such an improved hotplate is ideally suited for incorporation into an integrated sensor system.

A further object is to realize a novel heater concept based on a transistor-heating scheme that allows to heat hotplates very efficiently in terms of power consumption by avoiding to have a power transistor on the chip. In addition, such a transistor heating scheme is compatible to digital circuitry and is therefore much more versatile regarding the circuitry required.

A further object is to develop an integrated, low voltage driven sensor system of high stability by advantageous, integrated arrangement of the sensor components and the measuring and control components.

A still further object is to provide a design for an integrated sensor system allowing economical and efficient manufacturing of reliable sensor systems by utilizing proven semiconductor design and manufacturing technologies both for the hotplates and/or the integrated sensor systems.

It is a further object to provide arrays of hotplates covered with different sensitive materials and operated at different temperatures on a single chip along with multiplexer circuitry to increase the gas sensing performance by improved recognition and quantification of analyte gases.

It is a further object to provide microsensor systems with integrated features such as self test capability, self-identification and networking capability as well as enhanced operation features such as pulse mode or temperature modulation of the hotplate sensors.

### THE INVENTION

The present invention has two aspects. A first aspect is the creation of a new generation of integrated microsensor systems using micro-hotplates and associated circuitry on the same chip, leading to a compact, low-power, integrated device. A second, related aspect is the creation of a novel micro-hotplate type and heating scheme to be preferably incorporated into an integrated microsensor system according to the first aspect above. All this is preferably designed to be manufactured in proven industrial semiconductor technology, here CMOS technology.

Starting with the second aspect, one design of the novel micro-hotplate employs an advantageous heating transistor arrangement directly on the membrane which can be driven by a low-voltage supply. If a FET is used as heater, the temperature of the membrane can be statically and dynamically controlled by the gate voltage. It can be shown that almost linear characteristics above 100° C. are achievable. Such a device may be fabricated in proven industrial 0.8 μm CMOS-technology. This novel micro-hotplate is a major step towards the integration of metal-oxide chemical sensors with circuitry on the same chip and allows the creation of totally new microsensor systems.

Another advantageous design of the micro-hotplate has a novel ring-shape resistor configuration of the heater, which ensures homogeneous temperature distribution on the so-called membrane. By, e.g. a circular or octagonal shape of the heater, the overall power consumption of the heated area can be significantly reduced.

It is obvious that the integration of further components into the sensor system chip, which already includes the sensor with its heating elements, leads to a number of further advantages. This integration allows to amplify, and/or process otherwise, e.g. digitize, the sensor signals directly on the chip. This in turn increases speed and reduces noise of the sensor system, thus generally improving its signal-to-noise characteristics, hence its sensitivity, stability and reliability. It also enables sensor and system or sensor terminal miniaturization.

Integration further allows feedback and/or control signals for the heater to be derived and processed directly on the chip, thus stabilizing the sensor system's output.

The above addressed integration also reduces the number of external connections necessary to and from the chip, thus simplifying the design of the whole sensor device, reducing connection complexity and packaging costs. This, again, improves the reliability of the sensor system and positively affects the overall manufacturing profitableness.

Integration also drastically reduces the overall system size and thus enables effective miniaturization of the overall sensor unit.

Integration further allows to reduce the overall power consumption of such an integrated sensor system. This, in turn, leads to small, low-power sensor system chips, which are well-suited for portable, lightweight, low-power sensor devices.

Integration also enables to realize arrays of hotplates on a single chip along with multiplexer circuitry to increase the gas sensing performance.

Integration significantly reduces the number of external components needed and saves assembly time in producing the system, thus rendering an integrated solution economically favorable.

Finally, integration enables the implemenation of smart features such as self-test capability, self-identification and networking capability, and enhanced operation features, such as pulse mode or temperature modulations of the hotplate sensors.

There will be more adavantages apparent to the person skilled in the art from the following description of various preferred embodiments.

### BRIEF DESCRIPTION OF THE DRAWINGS

In the following, several implementations of the invention will be described in detail and with reference to accompanying drawings showing details of these embodiments, namely:

FIG. 1 the principal layout of an integrated single chip sensor system according to the invention;

FIG. 2 a micrograph of an integrated single chip sensor system showing an implementation of the invention;

FIG. 3 a schematic cross-section of a micro-hotplate according to the invention;

FIG. 4 a micrograph of a first implementation of a membrane/hotplate;

FIG. 5 a micrograph of a second implementation of a membrane/hotplate;

FIG. 6 a micrograph of a third implementation of a membrane/hotplate;

FIG. 7 a micrograph of a fourth implementation of a

membrane/hotplate;

FIG. 8 a micrograph of a fifth implementation of a membrane/hotplate;

FIG. 9 a micrograph of the center of a still further implementation of a membrane/hotplate with external connections;

FIG. 10 a micrograph of the complete membrane/hotplate of FIG. 9 with external connections;

FIG. 11 a graph of temperature vs. supply voltage of the membrane/hotplate shown in FIGS. 9 and 10;

FIG. 12 a more detailed principal layout of an integrated single chip sensor system according to the invention;

FIG. 13 a micrograph of another integrated single chip sensor system showing a further implementation of the invention.

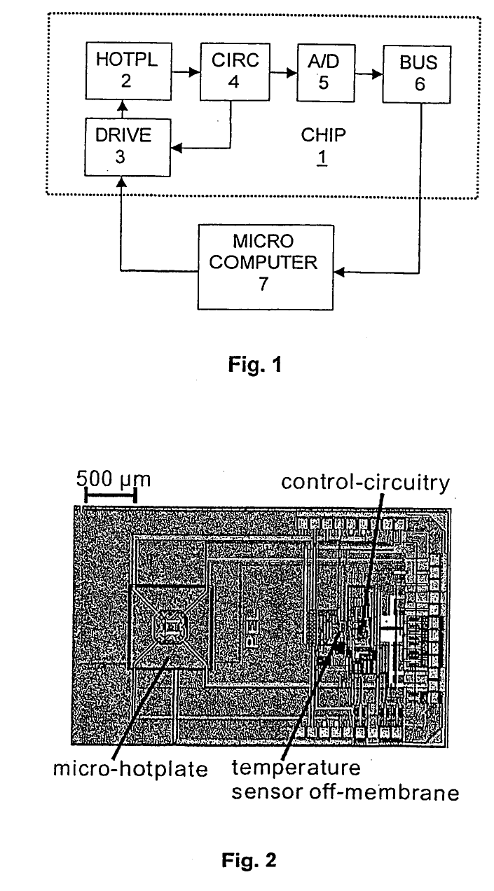

FIG. 1 shows the principal design of an integrated single chip sensor system according to the first aspect of the invention. The chip 1 comprises essentially:

a micro-hotplate 2 of, e.g., 300×300 μm up to 1×1 mm size, placed on a somewhat larger membrane, including the heater itself, electrodes of an impedance/conductivity measurement configuration, and at least one temperature sensor;

driving circuitry 3, connected to the hotplate 2, for driving the heater and controlling the temperature of the hotplate 2;

control and signal processing circuitry 4, connected to the hotplate and said driver circuitry 3, comprising an amplifier for the impedance/conductivity signals derived from the hotplate 2 and control circuitry for providing feedback to the driver circuitry 3,

an A/D converter 5; and

a bus or serial interface 6 to external processing units, the latter here shown as a microcomputer or microcontroller 7.

The function of the various elements and parts of chip 1 is understood by a person skilled in the art and from the prior art cited. It will also be understood from the following description of the embodiments.

FIG. 2 shows a micrograph of an embodiment according to the first aspect of the invention, namely an actually implemented, integrated single chip sensor system. Clearly identifiable are some elements of the system: the micro-hotplate on the membrane, here an essentially square-shaped design, with its connections to the control circuitry, the control circuitry itself, and one of the temperature sensors, here the off-membrane temperature sensor. Details of the sensor system and the micro-hotplate/membrane will be shown and described in the following figures.

FIG. 3 is a schematic cross-section of a micro-hotplate and thus relates to the second aspect of the invention, which is essentially of micromechanical nature. The hotplate is located in a so-called membrane. Since one of the objectives of this invention is to use standard industrial CMOS or similar semiconductor processes to realize the transducer and circuitry components of the sensor system, the materials available for the micromechanical design are restricted to various dopings of the Si-substrate, some dielectric layers (silicon nitride, silicon oxide) usually used for isolation and passivation, different poly-Si layers, and different Al-metallizations. After the CMOS-process, dedicated post-processing steps such as back side etching or deposition of the sensitive layers are performed, as usual and known in the semiconductor technology.

The general features of such an essentially micromechanical membrane/hotplate include essentially the subunits membrane, heater, temperature sensor(s) and electrodes for the conductivity measurements.

FIG. 3 shows a cross-section of the membrane 11. The hotplate has a heated area of 300×300 μm on a membrane of 500×500 μm, a size corresponding to typical lateral dimensions of a conductivity microsensor. This size is approximately equivalent to the one shown in FIG. 2 and was chosen with respect to the precision limits of the currently available coating methods. The membrane 11 consists of dielectric layers and is released by anisotropic KOH-etching from the wafer backside with an electrochemical etch stop-technique.

The heater 13 is a poly-silicon resistor. Different meander and ring-shaped heater structures with an appropriate electrical resistance may be used on the membrane, as will be shown below. The maximum operation temperature of 400° C. is achieved with a standard supply voltage of 5V. However, to sinter the nanocrystalline SnO₂, higher temperatures up to 500-550° C. might be necessary in some cases. If the heater 13 is to be used for such high temperature annealing, it has to be protected against accelerated aging by, e.g., electro-migration processes. Hence the use of the heater 13 for the sintering process should be avoided. Therefore, the implementation of an additional high-voltage (≈10 V) heater to achieve the required annealing temperature might be considered. Another solution could include keeping the whole chip at an elevated temperature or heating the membrane locally by an external source during the annealing process. With both solutions, the necessary annealing temperature can be reached at reduced power consumption in the hotplate and without imposing high current densities on the heating resistor.

An n-well Si-island 12 is realized underneath the heater 13 using an electrochemical etch stop technology. This Si-island improves the temperature uniformity across the membrane 11 and offers some mechanical advantages. Depending on the heater configuration chosen, the heated area will have a square, octogonal, or circular shape. The latter, though more difficult to achieve in conventional technology, may be preferable both in view of the heating efficiency and in view of the circular symmetry of a (chemical) sensing layer fabricated by droplet deposition. It is obvious to the person skilled in the art that different designs may be realized to evaluate and improve mechanical and thermal properties of the hotplate.

Also, different temperature sensors may be used. Shown in FIG. 3 are a central temperature sensor 14 and an off-membrane temperature sensor 15. To achieve the desired resistive temperature measurement, Al, poly-Si and/or n-Si diffusion resistors may be placed on the membrane. A plurality of sensors may be distributed over the heated area for measuring lateral temperature variations. A thermopile configuration may also be used. Also, the bulk chip temperature of the chip shown in FIG. 1 (not the membrane) can be measured either resistively or by an integrated active temperature sensor circuit.

The contact electrodes 16 consist of the Al-electrodes of the CMOS-process covered with a platinum, gold or other noble metal layer to achieve better electrode contact to the deposited sensitive layer. The usual nitride passivation is opened in the electrode area to ensure tight attachment of the sensitive layer and the top metal layer (noble metal) to the CMOS aluminum. Interdigitated electrodes and pairs of parallel electrodes with varying center-to-center distance may be used. Additionally, a variety of metals and noble metals may serve as top electrode layers.

The temperature of the chip 1 (FIG. 1) is expected to increase by approximately 4-6° C. over ambient temperature due to the heat flow from the membrane 11. The thermal isolation seems to work well, since the dielectric membrane materials are good thermal insulators and the rather thick silicon chip acts as a heat sink. Consequently, heat transfer from the membrane 11 to the chip 1 is no problem.

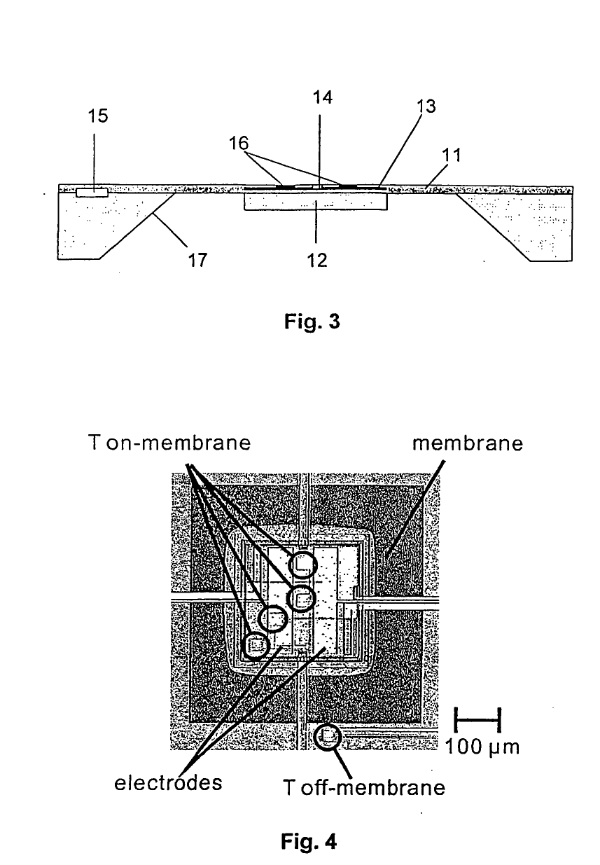

FIGS. 4 to 10 show various embodiments of the membrane/hotplate and shall be described in the following.

FIG. 4 is a micrograph of a first embodiment, a test structure, of a membrane manufactured according to the layout shown in FIG. 3. It is a preliminary design chip manufactured to confirm simulations made beforehand, exhibiting two on-membrane temperature sensors and two off-membrane temperature sensors at 50 μm and 200 μm distance from the membrane. The latter sensor is not shown on FIG. 4. The temperature sensors are realized as Al-resistors. Measurements on this preliminary design chip confirmed the simulations.

With the test structure of FIG. 4 it was found that the measured temperature increase off-membrane is (approximately linearly) proportional to the applied temperature on-membrane and amounts to approximately 2% of the temperature on-membrane. If the membrane temperature is, e.g. 400° C., the temperature at a distance of less than 50 μm from the membrane is 6-7° C. above ambient temperature. These measured results are in excellent agreement with the simple modeling/simulating done beforehand.

Due to packaging requirements and mechanical stability reasons, any circuitry has to be located at a distance of more than 300 μm from the membrane. It is clear from the above that the temperature increase at this distance is negligible.

In contrast to prior art approaches, where the sensor membrane/hotplate and the circuitry are separate, the present invention also aims at integrating the hotplates as part of a smart single-chip chemical microsystem with low-voltage (5V) circuitry components, preferably in commercial CMOS-technology. For this purpose, some test membranes have been developed to investigate temperature homogeneity. A special heater design was developed in order to achieve temperatures of up to 400° C. with a symmetric and homogeneous temperature distribution, using a supply voltage of less than 5V. Membranes with n-well silicon islands underneath were fabricated using a post-processing electrochemical etch stop technology.

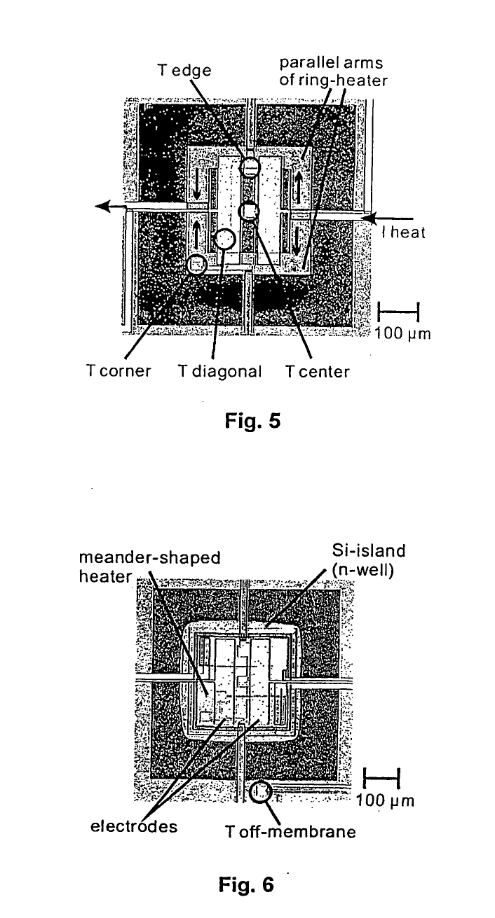

The first test membrane is shown in FIG. 5. Again, it is 500×500 μm in size, has a heated area of 300×300 μm, and has a polysilicon heater. The membrane is fabricated by an industrial 0.8 μm-CMOS process. The polysilicon heater is designed as practically square ring structure of two C-shaped arms as may be seen from FIG. 5. The two heater arms are connected in parallel, thus reducing the overall heater resistance; they form a symmetrical guarding ring around the hotplate and thus provide symmetrical heat generation and conduction. A number of temperature sensors is distributed over the membrane, indicated by “T” in the figure: a central sensor, an edge sensor, a diagonal sensor and a corner sensor. These sensors provide a very detailed recording of the temperature distribution over the membrane: The overall temperature deviations over the membrane are less than 2% of the applied temperature. In the sensing area, the temperature deviations are less than 1% of the adjusted temperature, even without the use of additional heat spreaders. This clearly demonstrates the technical quality of this concept

A micrograph of the second test membrane is shown in FIG. 6. The membrane again is 500×500 μm in size, has a heated area of 300×300 μm, and exhibits a polysilicon heater. This heater is meander-shaped. Furthermore, there is a 6 μm-thick n-well Si-island underneath the heater, being realized by an electrochemical etch-stop technology developed at the inventors' laboratories. The Si-island stabilizes the membrane and enhances the homogeneity of the temperature distribution. Also integrated are resistive temperature sensors monitoring the heat distribution at four characteristic locations, similar to the temperature sensors shown in FIG. 5. Some off-membrane sensors record the temperature variation on the chip, but not all of them are shown in FIG. 6. Two noble-metal electrodes on the Al-metallization are provided for the conductivity measurements.

The four temperature sensors distributed over the hotplate area, as shown in FIGS. 5 and 6, serve to assess the temperature homogeneity on the chip. The sensor in the center is assigned the temperature reference point and the temperature difference to the other sensors is measured. With the ring heater according to FIG. 5, the center is colder than the diagonals and edges. The edge is the hottest point, since the edge sensor is located directly on the heater. The Al-electrodes promote the heat distribution due to their good heat conductivity. The overall result is a temperature variation for the dielectric membrane of less than 2% without any additional heat spreader like a metal plate or a silicon plug. This excellent result is far superior to any data reported in the literature so far.

As may be expected, the membrane shown in FIG. 6 with the Si-island provides also a good temperature homogeneity, since the Si-island serves as a heat spreader. However, the temperature in the corners deviates significantly. Still, the more complicated heating scheme ensures an evenly distributed heating of the central hotplate.

The designs shown in FIGS. 5 and 6 are both promising regarding temperature homogeneity. Further optimization of the heating scheme shown there, including the use of a heat spreader (e.g. a silicon island), will certainly lead to even better results.

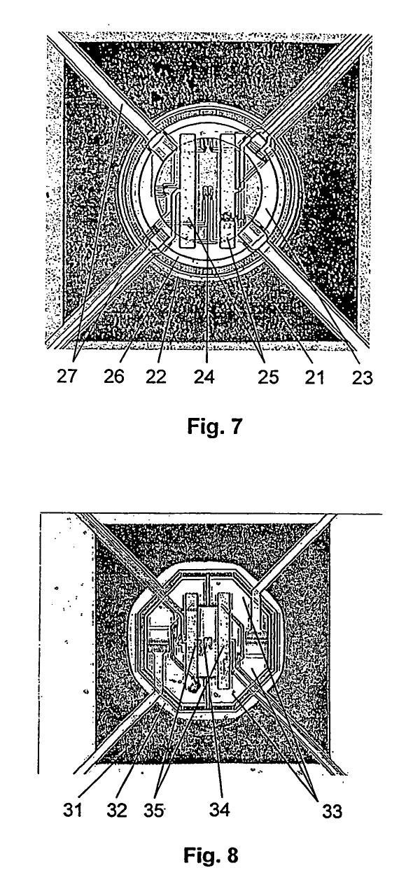

Such a further improvement is shown in FIG. 7, namely a novel circular structure of the heated area and the heater. In the monolithic layout , a combination of a ring-heater and a silicon island was chosen.

In the circular membrane of FIG. 7, a considerable part of the generated heat flows through the metal leads 27 connecting the heaters and temperature sensors to the bulk chip (not shown). However, in such a circular design, the distance between the heated area and the edge of the bulk chip is rather long and thus less heat is dissipated to the bulk chip. Additionally, a circular shape represents the natural shape of the SnO₂-drop, so that the metal oxide droplet formed with the usual technology of deposition of, e.g. a tin oxide droplet, preserves its shape. Consequently, the sensing layer is more uniform and not disturbed by a deviating membrane shape.

The membrane 21 shown in FIG. 7 is manufactured in CMOS-technology with a circular resistive ring heater 23 with parallel heating arms. The heater consists of two C-shaped arms open against each other and encompassing the hotplate. On the Si-island 22, a burn-in heater 26 may also be integrated. The membrane temperature is measured by a poly-Si resistor 24 located in the center. A temperature sensor network (not shown) may be integrated on the bulk chip in order to assess temperature homogeneity on the membrane.

The device shown in FIG. 7 is coated with SnO₂ by droplet deposition. Due to the membrane geometry, the droplet maintains its shape and is not distorted (as mostly when deposited on a membrane with rectangular shape). The droplet's shaping may be improved further by introducing additional topographic structures along the edge of the heated area.

FIG. 8 shows another device manufactured in CMOS-technology. In this embodiment, the heated area of the membrane 31 is surrounded by an octogonal-shaped heater which again consists of two electrically parallel arms 33 as in FIG. 7. The heater is made of p-doped Si. The Si-island 32, the contact electrodes 35, and the central temperature sensor 34 are arranged essentially as shown in FIG. 7. Again, droplet deposition of the usual metal oxide for the sensing layer leads to practically perfect results because of the almost round shape of the hotplate.

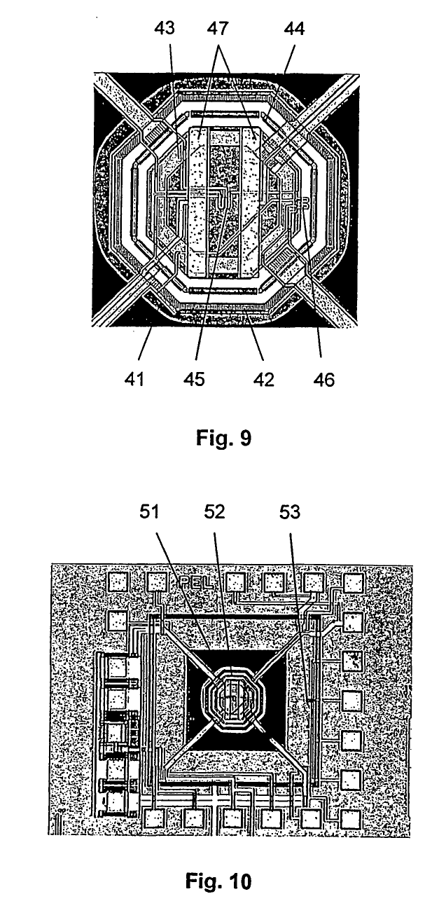

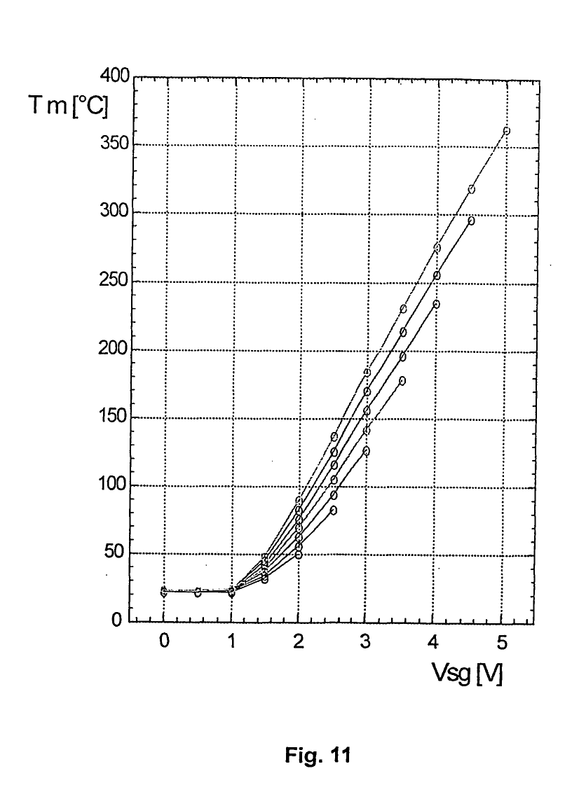

FIGS. 9 and 10 show another octogonal implementation in CMOS-technology. This time, however, a transistor-type heater is incorporated in the silicon island. Transistor type heaters are easy to implement and offer significant other advantages as will be described. The hotplate cross section is principally identical to that shown in FIG. 3. FIG. 9 is the close-up of the hotplate, FIG. 10 a micrograph of the whole membrane with the integrated heater and the external connections. Both figures together will be described hereinafter.

The size of the whole membrane shown in FIG. 10 is 500×500 μm. To ensure a good thermal isolation, only the dielectric layers of the industrial CMOS-process form part of the membrane 51. As more clearly visible in FIG. 9, the inner section of the membrane exhibits an octagonally shaped n-well Si island 41 of 300 μm base extension underneath the dielectric layers. The membrane 51 is released using KOH wet etching with an electrochemical etch stop technique as already mentioned. The n-well 41 is electrically insulated and also serves as a heat spreader. A considerable part of the heat is dissipated via the metal connections 52. The octagonal shape provides a relatively long distance between the heated membrane area and the cold bulk chip 53. In contrast to FIGS. 4 through 8, a novel PMOS heater transistor design 44, again in a ring-shape configuration, with 5 μm gate length and 720 μm overall width is integrated into the Si-island 41. This shape of the heater transistor leaves enough space to implement the resistive temperature sensors 45 and 46 in poly-Si. The central sensor 45 in the midst of the membrane is used to determine the membrane temperature, the second, lateral sensor 46 is used to assess temperature homogeneity. An additional resistive poly-Si-heater 43 is integrated on the membrane as well. Both heaters 43 and 44 may be used in parallel.

FIG. 11 shows the measured membrane temperature Tm versus the transistor gate voltage Vsg for different constant heating voltages Vsd, the latter increasing by 0.5V from 2V to 5V. The lowermost curve is the 2V result, the top one for 5V. The n-well Si-island 41 is in this case connected to the source. It is apparent that the hotplate can be heated up to 350° C. using a low-voltage power supply and that the temperature can be well controlled by the gate-voltage. Moreover, the heating characteristic is almost linear above 100° C., which simplifies the control of the membrane temperature.

Due to the low thermal mass of the hotplate ensemble and due to the fast response of heaters and circuitry, any of the resistive or transistor heaters in FIGS. 5 through 10 can be operated in a dynamic mode by modulation of either the resistor current or the transistor gate voltage. It will be obvious to a person skilled in the art how to implement such a dynamic heater mode.

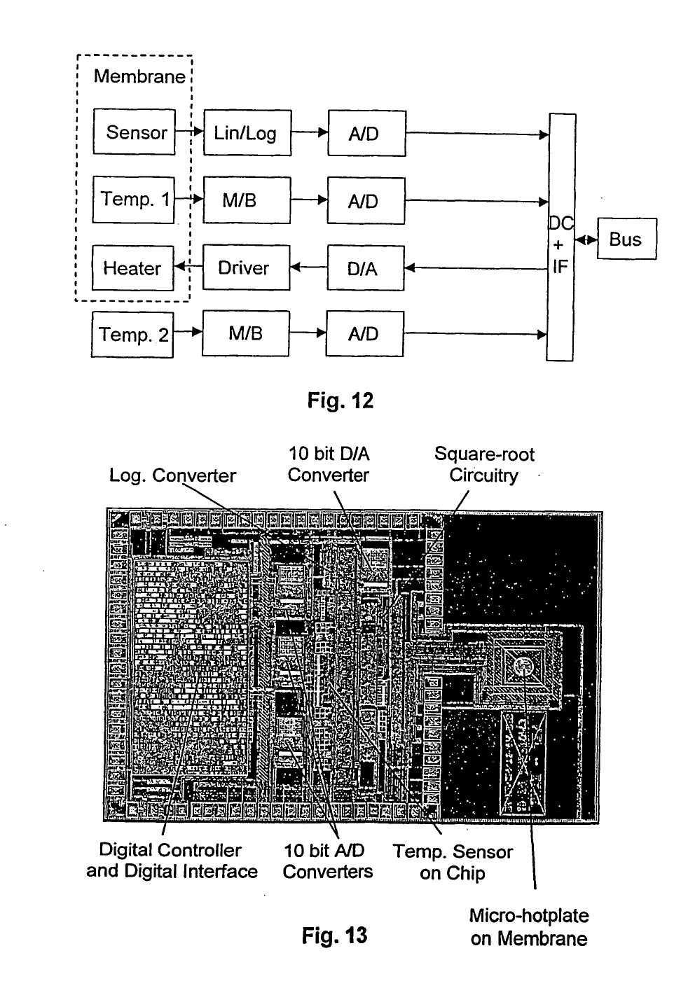

FIG. 12 finally shows a complete block diagram of an exemplary microelectronics design in some more detail as FIG. 1. The main circuitry components must meet the following needs:

Controlling the membrane temperature

Measuring the temperature on the membrane

Measuring the temperature on the chip

Measuring the SnO₂ resistance

Measuring the driving current of the heater(s)

Providing interfaces

In the block diagram shown in FIG. 12, the temperature control of the membrane is implemented using an analog proportional controller. A digital PID (Proportional-Integrative-Derivative) controller may be used as alternative if more flexibility to the desired temperature waveform is desired. Using an embedded digital PID controller would even further improve the stability of the system and reduce the steady-state deviation. The routine operating temperature range of the membrane is from 200° C. to 400° C.

The temperature on the membrane is measured using a poly-Si resistor as temperature sensor (Temp. 1). The accuracy of the measured temperature is determined from experimental data, i.e. the known change of poly-Si resistivity at high temperatures. Additionally or alternatively, Pt-thermoresistors, which can be deposited on the membrane, may be used.

The temperature on the bulk chip is measured using the voltage difference of two Vbe junctions working at different current densities (Temp. 2). The expected accuracy of the measured temperature is about ±1% after calibration. The resistance of the SnO₂ resistor (Sensor) is measured using a linear-to-logarithmic converter (Lin/Log) based on the exponential behavior of the Vbe junction.

A suitable choice for the interface circuitry (DC+IF) may be an I2C serial interface, a communication standard developed by Philips, Eindhoven, NL.

Such an I2C serial interface allows for connecting the chip to an external communication microcontroller via a standard bus. This interface not only enables the collection of information from the chip, such as the digital values of the membrane temperature, the SnO₂ resistance, and the temperature on the chip, but also allows for changing the parameters of the digital PID controller. It also allows for operating the chip on a bus system, which means that many chips can be combined and operated on a single bus via digital interfaces.

Three 10-bit successive approximation analog-to digital converters (A/D) are used to acquire the digital values of the SnO₂ resistance (Sensor), the membrane temperature (Temp. 1) and the temperature on the chip (Temp. 2). An analog circuit implementing a square-root function (Driver) is added to the heater driving circuitry. The purpose of this circuit is to get a linear and temperature-independent relationship between the power applied to the heating resistor and the necessary voltage.

A 10-bit digital-to-analog converter (D/A) reads the control signal from the digital PID controller and provides the analog input for the square-root circuitry (Driver). It shall be pointed out that any controller, digital or analog, on-chip or off-chip, suited to control a nonlinear time-variant second-order system may be used for controlling the membrane temperature.

Finally, FIG. 13 shows another implementation of the complete integrated sensor system, similar to FIG. 2. Though FIG. 13 is a mirror-image, i.e. reversed, compared to FIG. 12—the membrane is on the left of FIG. 12 whereas it is on the right in FIG. 13—it is easily understood which parts are equivalent. To avoid any doubts, the equivalents are listed in the following:

Equivalent components in FIGS. 12 and 13:

| | |
|---|---|
| Membrane | Micro-hotplate and Membrane |
| Sensor | not identified |
| Temp. 1 | not identified |
| Heater | not identified |
| Temp. 2 | Temp. Sensor on Chip |
| Lin/Log | Log. Converter |
| M/B (2x) | not identified |
| Driver | Square-root Circuitry |
| A/D (3x) | 10 bit A/D Converters |
| D/A | 10 bit D/A Converter |
| DC + IF | Digital Controller and Digital Interface |

With the listing above and with the description above of FIG. 12, the person skilled in the art should have no difficulty to completely interpret FIG. 13.

1. A microsensor system, comprising integrated on a single chip
a thermally insulated semiconductor structure (11, 21, 31, 51) including a heatable area,
at least one electrode (16, 25, 35, 47) on said heatable area,
a microheater (13, 23, 33, 43, 44) for heating said heatable area, and
at least one first integrated circuit for controlling power and/or temperature of said microheater and/or temperature of said heatable area.

2. The microsensor system according to claim 1, comprising
at least one further integrated circuit for obtaining and/or processing signals derived from the at least one electrode (16, 25, 35, 47), said second integrated circuit preferably including amplifiers and/or signal processing means.

3. The microsensor system according to claim 1, comprising
at least one further integrated circuit for controlling the potential applied to the at least one electrode (16, 25, 35, 47).

4. The microsensor system according to any preceding claim, further comprising
at least one temperature sensor (14, 15, 24, 34, 45, 46), connected to the at least one first integrated circuit, for measuring the temperature of at least part of the thermally insulated structure.

5. The microsensor system according to claim 4, further comprising
at least one temperature sensor (53), connected to the at least one first integrated circuit, for measuring the temperature on the bulk chip outside the thermally insulated structure.

6. The microsensor system according to claim 1, wherein
the heatable area is essentially of round, elliptic, or polygonal shape.

7. The microsensor system according to claim 1, wherein
the microheater (43) is a resistive heater, preferably made of or including polysilicon and/or metal.

8. The microsensor system according to claim 1, wherein
the microheater (13, 23, 33, 44) is a transistor, preferably a PMOS transistor.

9. The microsensor system according to claim 7 or 8, wherein
the microheater (13, 23, 33, 43, 44) is or includes one or more heating elements of essentially round, elliptic, or polygonal shape, or wherein
the microheater (13, 23, 33, 43, 44) includes a plurality of heating elements forming in their totality a microheater of essentially round, elliptic, or polygonal shape.

10. The microsensor system according to one or more of claims 7 to 9, wherein
the microheater (13, 23, 33, 43, 44) is arranged along the boundary of the heatable area.

11. The microsensor system according to claim 1, wherein
the heatable area is structured as a semiconductor island (12, 22, 32) placed on a membrane (11, 21, 31), said membrane providing thermal insulation of said heatable area from the semiconductor chip.

12. The microsensor system according to claim 11, wherein
the membrane (11, 21, 31) is structured by thinning or etching to provide the desired thermal insulation of the heatable area from the semiconductor chip.

13. The microsensor system according to any preceding claim, wherein
the at least one electrode (16, 25, 35, 47), preferably at least one pair of electrodes, is/are part of a conductive sensor arrangement on the thermally insulated structure (11, 21, 31, 51), said conductive sensor arrangement further comprising a sensitive layer, preferably a metal oxide, providing means for measuring the impedance of the conductive sensor arrangement.

14. The microsensor system according to any preceding claim, wherein
the heatable area and/or the membrane comprises topographical structural elements for
defining the form of said area or membrane and/or
controlling temperature distribution and/or
stabilizing said heatable area and/or membrane.

15. The microsensor system according to any preceding claim,
said system being a gas-sensitive system, in particular comprising an additional polymer-based, gas-sensitive microsensor.

16. The microsensor system according to any preceding claim, comprising monolithically integrated on a single chip:
a first plurality of microsensors and microheaters and
a second plurality of integrated circuits including at least one multiplexer for multiplexing measured values derived from said plurality of microsensors.

17. The microsensor system according to claim 16, further comprising monolithically integrated on a single chip
a parallel or serial interface for transferring signals representing values measured by one or more of the microsensors.

18. The microsensor system according to any preceding claim, further comprising
a temperature sensor (53) for measuring the chip temperature outside the heatable area.

19. A microsensor, especially for a microsensor system according to any of the preceding claims, comprising integrated on a single chip
a thermally insulated semiconductor structure (11, 21, 31, 51) as heatable area,
at least one electrode (16, 25, 35, 47) on said heatable area, and
a microheater (13, 23, 33, 43, 44) on or in said heatable area for heating the latter.

20. The microsensor of claim 19, further including
at least one temperature sensor (14, 15, 24, 34, 45, 46) integrated into the thermally insulated structure.

21. The microsensor of claim 19, wherein
the heatable area is essentially of round, elliptic, or polygonal shape.

22. The microsensor of claim 19, wherein
the microheater (43) is a resistive heater, preferably made of or including polysilicon and/or metal.

23. The microsensor of claim 19, wherein
the microheater (13, 23, 33,44) is a transistor, preferably a PMOS transistor.

24. The microsensor of claim 19, wherein
the microheater (13, 23, 33,43, 44) is or includes one or more heating elements of essentially round, elliptic, or polygonal shape or
includes a plurality of heating elements forming in their totality a microheater of essentially round, elliptic, or polygonal shape.

25. The microsensor of claim 19, wherein
the microheater (13, 23, 33, 43, 44) is arranged along the boundary of the heatable area.

26. The microsensor of claim 19, wherein
the heatable area is structured as a semiconductor island (12, 22, 32) placed on a membrane (11, 21, 31), said membrane providing thermal insulation of said heatable area from the semiconductor chip,
said membrane being preferably structured by thinning or etching to provide the desired thermal insulation of the heatable area from the semiconductor chip.

27. The microsensor of claim 19, wherein
the at least one electrode (16, 25, 35, 47), preferably at least one pair of electrodes, is/are part of a conductive sensor arrangement on the thermally insulated structure (11, 21, 31, 51),
said conductive sensor arrangement further comprising a sensitive layer, preferably a metal oxide, for measuring the impedance of said microsensor.

28. The microsensor of claim 19, wherein
the heatable area and/or the membrane comprises topographical structural elements for
defining the form of said area or membrane and/or
controlling temperature distribution and/or
stabilizing said heatable area and/or membrane.

29. The microsensor of any of the preceding claims 19 to 28,
being a gas-sensitive microsensor, additionally comprising preferably a polymer-based, gas-sensitive microsensor.

30. A method for manufacturing a microsensor or an integrated microsensor system according to one or more of the preceding claims, characterized by
the use of CMOS, BiCMOS or Bipolar semiconductor manufacturing technology.
